(19) United States
(12) Patent Application Publication
(10) Pub. No.: US 2023/0245942 A1
(43) Pub. Date: Aug. 3, 2023

(54) SEMICONDUCTOR DEVICE PACKAGE WITH INTEGRAL HEAT SLUG

(71) Applicant: Texas Instruments Incorporated, Dallas, TX (US)

(72) Inventors: Kwang-Soo Kim, Sunnyvale, CA (US); Woochan Kim, San Jose, CA (US); Vivek Arora, San Jose, CA (US); Ken Pham, San Jose, CA (US)

(21) Appl. No.: 17/589,761

(22) Filed: Jan. 31, 2022

(51) Int. Cl. H01L 23/34; H01L 23/495; H01L 23/00; H01L 23/31; H01L 21/48

(52) U.S. Cl. CPC H01L 23/34; H01L 23/49555; H01L 24/06; H01L 23/3107; H01L 21/4803; H01L 24/48; H01L 2224/06135; H01L 2224/48175

(57) ABSTRACT

A described example includes: a heat slug having a board side surface and an opposite top side surface; a package substrate mounted to the heat slug, the package substrate including overhanging leads extending over the board side surface of the heat slug, the package substrate having downset portions including a downset rail that runs along one side of a die mount area; at least one semiconductor device having a backside surface mounted to the board side surface of the heat slug; electrical connections coupling bond pads of the semiconductor device to the overhanging leads of the package substrate and to the downset rail; and mold compound covering the at least one semiconductor device, the electrical connections, a portion of the leads and the board side surface of the heat slug, the top side surface at least partially exposed from the mold compound.

### TECHNICAL FIELD

This relates generally to packaging electronic devices, and more particularly to semiconductor devices in molded semiconductor device packages.

### BACKGROUND

Processes for producing semiconductor device packages include mounting a semiconductor device to a package substrate and covering the electronic devices with mold compound to form packaged devices. The molding processes may be done on single units, or may be done on multiple electronic devices simultaneously. The devices may be arranged on a package substrate in a strip of devices adjacent to one another, or in a two dimensional array of devices in rows and columns on a package substrate, such as lead frame strips or arrays. Once the molded packages are completed, the packaged semiconductor devices are separated from one another and from the package substrate. In one method to separate the devices from one another, a saw is used. The saw cuts through the mold compound and through the package substrate materials along saw streets defined between the semiconductor device packages, to separate the devices. Other cutting tools such as lasers can be used.

For power semiconductor devices, such as power field effect transistors (FETs) for example, semiconductor device packages should have increased thermal dissipation. The semiconductor device packages can include thermal pads or heat slugs. Incorporating a heat slug with an exposed surface for thermal dissipation can greatly improve the ability of the packaged semiconductor device to carry current at higher voltages, for example several hundred volts, because heat generated by the semiconductor devices within the package can be rapidly dissipated. In addition, the inductance of connections within the semiconductor device package can adversely affect device performance.

### SUMMARY

In a described example, an apparatus includes a heat slug having a board side surface and an opposite top side surface; a package substrate mounted to the heat slug, the package substrate including overhanging leads extending over the board side surface of the heat slug. The package substrate has downset portions including a downset rail that runs along one side of a die mount area on the board side surface of the heat slug, the downset portions of the package substrate are mechanically attached to and electrically coupled to the board side surface of the heat slug. The package substrate has the overhanging leads spaced from and electrically isolated from the heat slug; at least one semiconductor device having a backside surface mounted to the board side surface of the heat slug, the at least one semiconductor device having bond pads on a device side surface facing away from the board side surface of the heat slug; and electrical connections coupling bond pads of the semiconductor device to the overhanging leads of the package substrate and to the downset rail. Mold compound covers the at least one semiconductor device, the electrical connections, a portion of the leads of the package substrate, and the board side surface of the heat slug, while the top side surface of the heat slug at least partially exposed from the mold compound.

### BRIEF DESCRIPTION OF THE DRAWINGS

FIG. 1A illustrates in a projection top view a small outline package (SOP), FIG. 1B illustrates in a projection bottom view the small outline package, and FIG. 1C illustrates in an end view a portion of the small outline package of an arrangement. FIG. 1D is a plan view of a board side of a heat slug and lead frame of the small outline package, FIG. 1E is a cross sectional view illustrating an attachment between a heat slug and a lead frame of an arrangement, FIG. 1F is another plan view illustrating an alternative attachment for a heat slug and a lead frame, FIG. 1G is a plan view illustrating electrical connections between semiconductor devices and a lead frame of an arrangement.

FIG. 2 illustrates, in a circuit diagram, a gate driver and a power FET useful with an arrangement.

FIG. 3 illustrates, in a flow diagram, selected steps for forming an arrangement.

FIGS. 4A-4F illustrate, in a series of end views and plan views, the results of selected steps in manufacturing a packaged semiconductor device of the arrangements using the method shown in FIG. 3.

### DETAILED DESCRIPTION

Corresponding numerals and symbols in the different figures generally refer to corresponding parts, unless otherwise indicated. The figures are not necessarily drawn to scale.

Elements are described herein as “coupled.” The term “coupled” includes elements that are directly connected and elements that are indirectly connected, and elements that are electrically connected even with intervening elements or wires are coupled.

The term “semiconductor device” is used herein. A semiconductor device can be a discrete semiconductor device such as a bipolar transistor, a few discrete devices such as a pair of power FET switches fabricated together on a single semiconductor die, or a semiconductor die can be an integrated circuit with multiple semiconductor devices such as the multiple capacitors in an A/D converter. The semiconductor device can include passive devices such as resistors, inductors, filters, sensors, or active devices such as transistors. The semiconductor device can be an integrated circuit with hundreds or thousands of transistors coupled to form a functional circuit, for example a microprocessor or memory device.

The term “semiconductor device package” is used herein. A semiconductor device package has at least one semiconductor device electrically coupled to terminals, and has a package body that protects and covers the semiconductor die. In some arrangements, multiple semiconductor devices can be packaged together. For example, a power field effect transistor (FET) semiconductor device and a second semiconductor device (such as a gate driver die or a controller die) can be packaged together to from a single packaged electronic device. Additional components such as passives can be included in the packaged electronic device. The semiconductor device is mounted with a package substrate that provides conductive leads, a portion of the conductive leads form the terminals for the packaged device. In wire bonded semiconductor device packages, bond wires couple conductive leads of a package substrate to bond pads on the semiconductor device. The semiconductor device package can have a package body formed by a thermoset epoxy resin mold compound in a molding process, or by the use of epoxy, plastics, or resins that are liquid at room temperature and are subsequently cured. The package body may provide a hermetic package for the packaged device. The package body may be formed in a mold using an encapsulation process, however, a portion of the leads of the package substrate are not covered during encapsulation, these exposed lead portions form the terminals for the semiconductor device package.

The term “package substrate” is used herein. A package substrate is a substrate arranged to receive a semiconductor die and to support the semiconductor die in a completed semiconductor device package. Package substrates useful with the arrangements include conductive lead frames, which can be formed from copper, aluminum, stainless steel, steel and alloys such as Alloy 42 and copper alloys. The lead frames can include a die pad with a die side surface for mounting a semiconductor die, and conductive leads arranged near and spaced from the die pad for coupling to bond pads on the semiconductor die using wire bonds, ribbon bonds, or other conductors. In example arrangements, a heat slug is attached to the package substrate, and the heat slug has a die mounting area for mounting semiconductor devices. The lead frames can be provided in strips or arrays. The conductive lead frames can be provided as a panel with strips or arrays of unit device portions in rows and columns. Semiconductor devices can be placed on respective unit device portions within the strips or arrays. A semiconductor device can be placed on a die mount area for each packaged semiconductor device, and die attach or die adhesive can be used to mount the semiconductor devices. In wire bonded packages, bond wires can couple bond pads on the semiconductor devices to the leads of the lead frames. The lead frames may have plated portions in areas designated for wire bonding, for example silver, nickel, gold, or palladium plating can be used. After the bond wires are in place, a portion of the package substrate, the semiconductor device, and at least a portion of the die pad can be covered with a protective material such as a mold compound. More than one semiconductor device can be mounted to a package substrate for each unit.

The term “downset” is used herein to describe portions of a package substrate such as a lead frame. A downset is a portion of a package substrate that is mechanically pushed from a first position in a first horizontal plane to lie in a second horizontal plane spaced from the first horizontal plane. In an example arrangement, a package substrate, a metal lead frame, includes overhanging leads that lie in a first horizontal plane and extend over a board side surface of a heat slug, and a downset rail that lies in a second plane that is beneath the overhanging leads. The downset rail is attached to the board side surface of the heat slug. Some other portions of the lead frame are downset to form mounting areas attached to the heat slug, and some additional leads of the lead frame have portions that are downset to connect to the downset rail.

The term “power FET” is used herein. As used herein, a power FET is field effect transistor (FET) device arranged to carry current between a drain and a source terminal, and the power FET is capable of carrying current at high voltages, that is voltages greater than 100 Volts and up to 1000 Volts, and can operate at up to 10 kilowatts. The power FET can be a silicon, silicon carbide (SiC) , or gallium nitride (GaN) FET device. Semiconductor packages for semiconductor devices carrying current at these voltages need thermal dissipation and inductance of certain connections are particularly important to performance, including ground connections.

The term “heat slug” is used herein. A heat slug is a piece of thermally conductive material. In the arrangements, the heat slug is integral to a semiconductor device package and semiconductor devices are mounted to the heat slug to be in thermal contact with the heat slug. In example arrangements, a heat slug has a board side surface, and an opposite top side surface that is exposed from the mold compound that forms the body of the package. Because of the material used and the exposed top side surface the heat slug can efficiently dissipate thermal energy, and in some examples, a heat sink or fin can be mounted to the top side surface of the heat slug to further increase thermal dissipation. In examples the heat slug can be of copper or aluminum, and may have platings to reduce corrosion or prevent tarnish, such as palladium, nickel, or gold plating, or combinations of these.

In packaging semiconductor devices, mold compound may be used to partially cover a package substrate, to cover the semiconductor devices, and to cover the electrical connections from the semiconductor devices to the package substrate. This can be referred to as an “encapsulation” process, although some portions of the package substrates are not covered in the mold compound during encapsulation, for example terminals are formed from leads that are exposed from the mold compound. Encapsulation is often a compressive molding process, where thermoset mold compound such as resin epoxy can be used. A room temperature solid or powder mold compound can be heated to a liquid state, and then molding can be performed by pressing the liquid mold compound into a mold. Transfer molding can be used. Unit molds shaped to surround an individual device may be used, or block molding may be used, to form the packages simultaneously for several devices from mold compound. The devices can be provided in an array of several, hundreds or even thousands of devices in rows and columns that are molded together.

After the molding, and following a cure process such as a timed cooling, the individual packaged semiconductor devices are cut from each other in a sawing operation by cutting through the mold compound and package substrate in saw streets which are designated cutting areas formed between the devices. Portions of the package substrate leads are exposed from the mold compound to form terminals for the packaged semiconductor device.

Leads for leaded packages are arranged for solder mounting to a board. The leads can be shaped to extend towards the board, and form a mounting surface. Gull wing leads, J-leads, and other lead shapes can be used. In a dual in-line plastic (DIP) package, the leads end in pin shaped portions that can be inserted into conductive holes formed in a circuit board, and solder is used to couple the leads to the conductors within the holes. In the arrangements, the leads are shaped to form feet at the ends for surface mounting to a printed circuit board using surface mount technology (SMT).

Elements are described herein as “lying in a plane”. A plane is a flat surface for which any two points lying in that same plane will lie. Elements lying in a plane will be in the same plane, however, in manufacturing some elements may be displaced from an intended location or may have irregular surfaces and may not be perfectly aligned with other elements intended to be in the same plane, as used herein, elements intended to lie in a plane are elements are lying in that plane. Certain planes are described herein as parallel to one another. As used herein, two planes are parallel when, if one plane is oriented in a horizontal position, the planes parallel to that plane are also in a horizontal position, and lines extending in two different parallel planes will never intersect one another. In manufacturing, elements intended to line in parallel planes may become displaced slightly due to manufacturing tolerances or process conditions, or may have irregular surfaces, as used herein elements intended to lie in parallel planes lie in parallel planes.

In the arrangements, a semiconductor device package includes at least one semiconductor device mounted to a heat slug. A package substrate is attached to the heat slug. The package substrate can be a conductive lead frame. The heat slug is a thermally conductive solid material such as copper or aluminum. In an example arrangement, the package substrate is a partial downset lead frame. The packaged device includes the integral heat slug. The partial downset leadframe is mechanically mounted and electrically coupled to the heat slug. A die mount area is formed on a board side surface of the heat slug with leads from the package substrate adjacent the die mount area. At least one semiconductor device is mounted in the die mount area with a backside surface attached to the heat slug, with the active devices and bond pads on the semiconductor device facing away from the surface of the heat slug. In an example, the at least one semiconductor device is a power field effect transistor (FET) device. A portion of the lead frame forms a downset rail that extends along one side of the die mount area, other portions of the lead frame form overhanging leads that extend out over the board side surface of the heat slug, but which are spaced from the surface of the heat slug, and which are electrically isolated from the heat slug. Electrical connections are made between bond pads on a device side surface of the semiconductor device and the leads on the package substrate. For some bond pads of the semiconductor device that are to be connected in common and to a ground, electrical connections are made to the downset rail. The electrical connections can be bond wires, ribbon bonds or conductive clips that couple bond pads to the leads or to the downset rail. The semiconductor device, the electrical connections, portions of the package substrate and portions of the heat slug are encapsulated in mold compound to form a packaged device. The heat slug has a top side surface opposite the board side surface exposed from the mold compound on the exposed side or “top” surface of the semiconductor device package, facing away from a board side of the semiconductor device package.

When the semiconductor device package is mounted to a circuit board, the exposed top side surface of the heat slug can dissipate thermal energy. The exposed top side surface of the heat slug can be used to mount a heat sink to increase thermal dissipation from the packaged semiconductor device. Because the semiconductor device has its backside directly mounted to the heat slug, the thermal dissipation from the packaged semiconductor device is especially efficient. In addition, use of the downset rail within the semiconductor device package reduces inductance of certain circuit connections (when compared to semiconductor device packages without the use of the arrangements which make these same connections on circuit board traces outside the semiconductor device package. This feature of the arrangements further increases the performance of the packaged semiconductor device. Use of the arrangements does not require changes to existing semiconductor device designs, circuit board designs or tooling, the package dimensions and pin positions and assignments are unchanged, so that only a slight increase in overall cost of the semiconductor device package occurs, due to a slight increase in cost of the partial downset package substrate (when compared to the cost of packages without the arrangements).

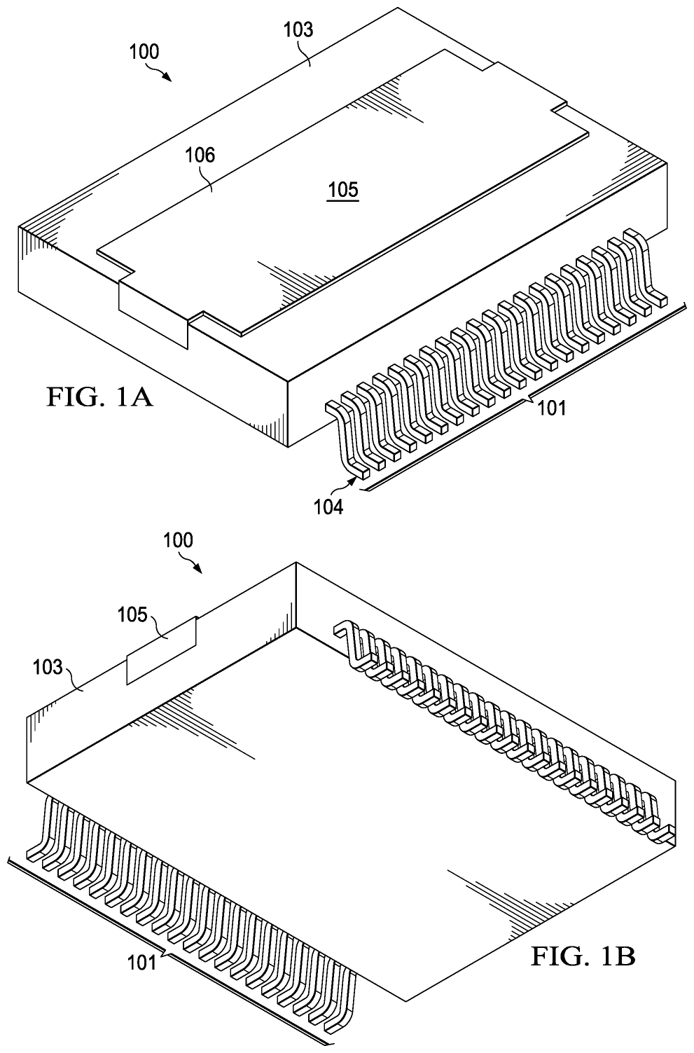

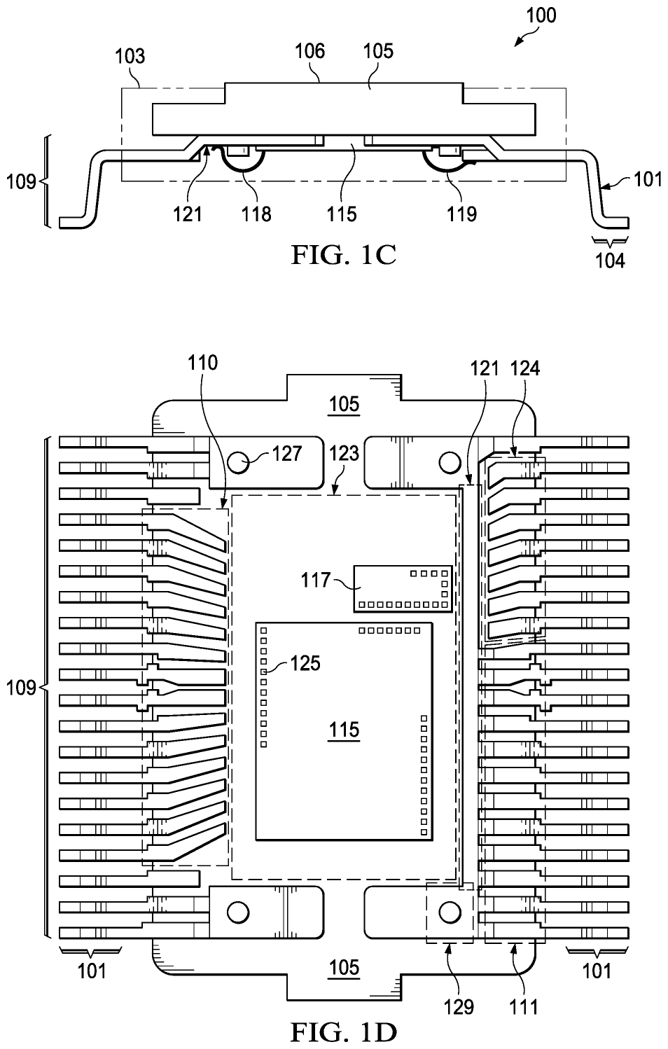

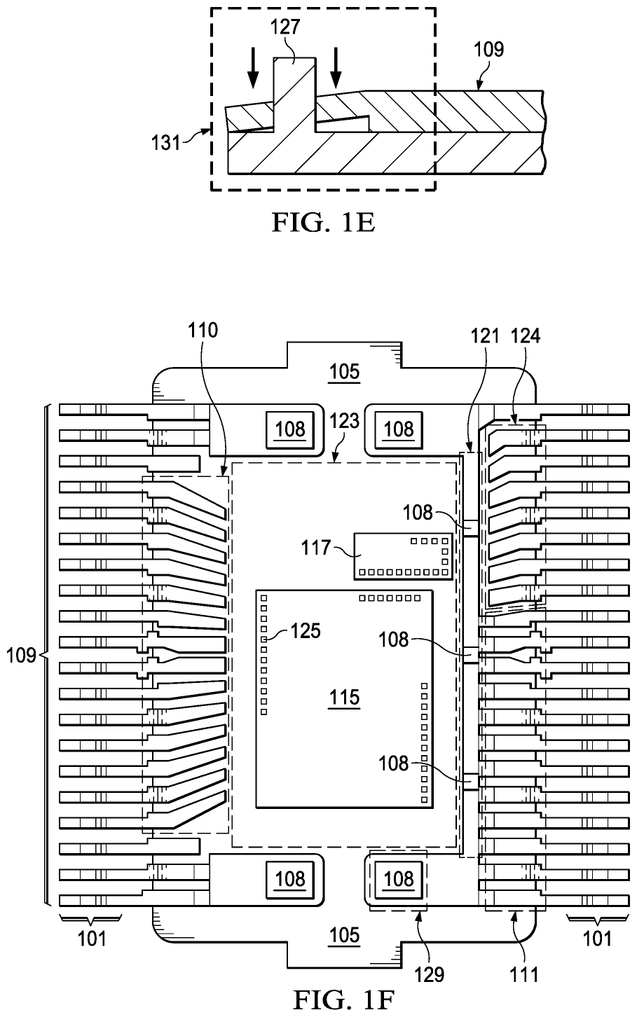

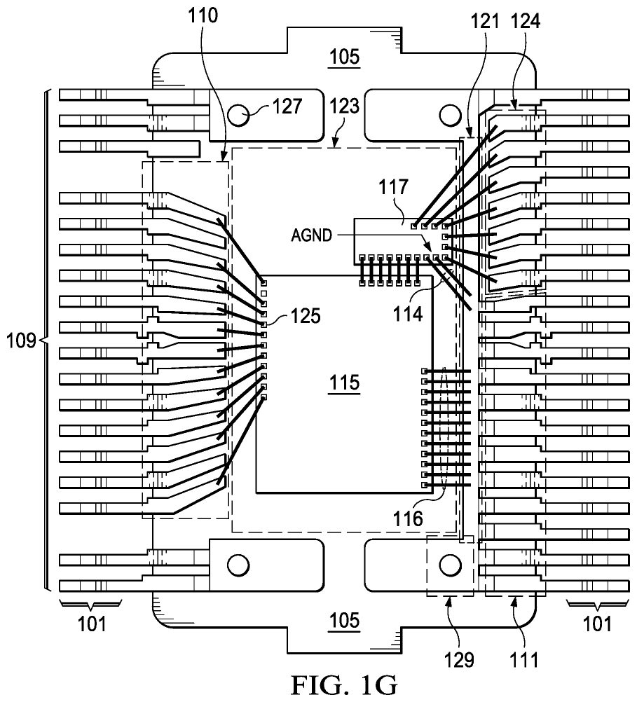

FIG. 1A illustrates, in a projection top view, a semiconductor device package 100, illustrated in a small outline (SOP) package with a heat slug having a partially exposed top side surface. SOP packages are one type of semiconductor device package that is useful with the arrangements. SOP packages are used for power devices and can be used for other devices. When in a smaller footprint the packages may be referred to as “shrink” SOP (SSOP) packages. When exposed thermal pads or exposed heat slugs are provided, the packages are sometimes designated HSSOP or HSOP packages. The arrangements can be used with a variety of package types where power FETs are provided in a molded semiconductor device package.

The semiconductor device package 100 has a body formed from a mold compound 103, for example the mold compound 103 can be a thermoset epoxy resin. Other mold compounds can be used including resins, epoxies, or plastics. Leads 101 are part of a package substrate 109 within the package 100, the leads 101 are exposed from the mold compound 103 and form electrical terminals for the packaged electronic device. The leads 101 in FIG. 1 are formed to provide gull wing shaped terminals that extend alongside the body of the semiconductor device package 100 with a foot portion 104 at the ends. A heat slug is integral to the semiconductor device package 100 and has an exposed surface 106. The semiconductor device package 100 can be mounted to a circuit board or module using surface mount technology (SMT). Sizes for packaged semiconductor devices are continually decreasing, and currently can be several millimeters on a side to less than one millimeter on a side, although larger and smaller sizes are also used. Future package sizes may be smaller. An example of HSSOP package with 36 pins has a body with a length of about 16 millimeters, and a width of about 11 millimeters, and has a height of about 3.5 millimeters. Other similar packages useful with the arrangements have more or fewer pins and the dimensions vary accordingly.

FIG. 1B is a projection view from the bottom side of the semiconductor device package 100, with the mold compound 103 forming the package body, and leads 101 extending from the mold compound. The heat slug 105 is partially visible, the exposed portion 106 facing away from the bottom of the semiconductor device package 100.

FIG. 1C is an end view of the semiconductor device package 100 with the features exposed to illustrate certain features. The mold compound 103 is shown covering a portion of a package substrate 109, which includes the leads 101. The heat slug 105 is partially covered by mold compound 103, while a top surface 106 of the heat slug 105 is exposed from the mold compound 103 to form a thermal dissipation surface. Package substrate 109 includes leads 101 have portions that extend from the mold compound 103 to form terminals, and the terminals are formed to include foot portions 104 for use in mounting the semiconductor device package 100 to a circuit board using surface mount technology, for example.

At least one semiconductor device 115 is shown mounted to the heat slug 105. When the packaged semiconductor device 100 is surface mounted to a circuit board, the semiconductor device 115 is arranged to face the circuit board (the bottom as oriented in FIG. 1C). The packaged semiconductor device 100 has a backside that is attached to the heat slug 105, for example by solder or by thermally conductive die attach film or die attach paste.

The semiconductor device 115 has bond pads (not shown for clarity of illustration) facing the circuit board in FIG. 1C that are electrically connected to leads of the package substrate 109. A wire bond 119 forms an electrical connection from a bond pad to a lead that is spaced from the heat slug 105. Bond pads useful with the arrangements can be of a copper or aluminum, and can be plated with metal layers to enhance bonding and reduce corrosion and ion diffusion, including gold, nickel, palladium, and multiple layer plating systems such as electroless nickel and immersion gold (ENIG) and electroless nickel, electroless palladium, immersion gold (ENEPIG).

Bond wire 119 is attached to an overhanging lead, which is electrically isolated from and extends over and parallel to the surface of the heat slug 105. A second bond wire 118 is shown extending from another bond pad on the semiconductor device 115 to a downset rail 121 of the package substrate 109. Bond wire 119 couples the bond pad on the semiconductor device 115 to the package substrate at the downset rail 121, which is electrically coupled and mechanically contacting the heat slug 105. As is further described below, the package substrate 109 includes the downset rail 121 that forms a low impedance and short distance path from the semiconductor device to a ground potential, reducing impedance for certain signals on semiconductor device 115.

In an example, the semiconductor device 115 can be a power FET device. Particular examples include power FET devices used to carry substantial current at voltages in the hundred Volt or higher voltage range, for example up to several hundred volts or a thousand volts, with power ratings of up to 10 kW. An example is a gallium nitride (GaN) FET. Another example is a silicon carbide (SiC) FET. These power FET devices provide rapid switching and low on resistance from drain to source (Rdson) when compared to a silicon metal oxide semiconductor (MOS) FET. The characteristics of these power FET devices including low Rdson resistance and low gate capacitance (compared to silicon MOSFETs) enable the GaN FET and SiC FET devices to deliver high currents in switching power supplies with faster switching and lower losses. The power FET can include several FET devices formed on a semiconductor substrate and coupled to operate in parallel, the individual transistors having drain, gate, and source connections to bond pads on the semiconductor device 115. In additional arrangements, a gate driver semiconductor device can be included in the semiconductor device package 100. In example arrangements, by packaging the gate driver semiconductor device with the power FET, inductances that would otherwise be caused by connections traversing bond wires, lead frame leads and package terminals, and then traversing circuit board traces to be connected, can be greatly reduced, since in the arrangements the electrical connections are shortened and include only the bond wires to an internal package conductor, a downset rail, that is a large conductor having low resistance. Performance is enhanced by integrating the two devices into a single semiconductor device package, and shortening connections between the two devices. In alternative arrangements, the power FET can be packaged using the arrangements without the gate driver device, and the gate driver device can be provided in another package. The power FET is then advantageously connected to the downset rail to shorten connections to a common source potential, for example a source connection to ground.

FIG. 1D illustrates the semiconductor device package 100 in a plan view looking from the board side. (Mold compound 103 is omitted in the plan view of FIG. 1D for clarity of illustration). The heat slug 105, which can be of copper, gold, aluminum, or of a plated metal that is thermally conductive, and which can include plating layers to reduce corrosion and tarnish formation, is shown with die mount area 123 on a board side surface. A first semiconductor device 115 and a second semiconductor device 117 are shown mounted on the heat slug 105. The first semiconductor device 115 can be a power FET such as a GaN FET, or an SiC FET, The second semiconductor device, in example arrangements, can be a gate driver device that is arranged to provide a gate signal to the power FET. Both the power FET 115 and the gate driver 117 are shown with bond pads 125 on a device side surface, the bond pads face away from the heat slug 105 are provide electrical connections to the semiconductor devices. In switching power supply applications, for example, the gate driver semiconductor device 117 can drive a pulse width modulated input signal to the gate input for the power FET. In addition the gate driver device 117 can receive control signals from and output status signals to a system for use in operating the devices. Example control signals include enable signals, slew rate control signals, and a pulse width modulated (PWM) gate switching signal. Example status signals include over temperature, over current, short circuit, under voltage, and fault signals. The gate driver semiconductor device may include circuitry arranged to protect the power FET when erroneous operation is detected by stopping current flow through the power FET, protecting the power FET from permanent damage.

The package substrate 109, which in the illustrated examples is a metal leadframe, is shown with connection areas 129 having a post 127. The metal leadframe can be a copper, plated copper, or other conductive metal used for leadframes such as Alloy 42, steel, and stainless steel. Copper is particularly useful as a leadframe material when used with a copper heat slug, as the two pieces then have similar thermal coefficients and reliable copper to copper bonds can be made. The package substrate 109 includes leads 101. Some leads 101 overhang the heat slug, for example overhanging leads 110 are arranged to be electrically connected to drain signals in the power FET, semiconductor device 115. Overhanging leads 110 extend over and parallel to the surface of the heat slug 105 so that the ends of the leads 110 are positioned to be wire bonded to the semiconductor devices, but each overhanging lead 110 is electrically isolated from the heat slug 105. In addition, the package substrate 109 includes a downset rail 121, and downset leads 111 that extend from it. The downset rail 121 runs alongside the die mount area 123 and is positioned to receive wire bonds that connect to common source terminals of the power FET 115. The downset leads 111 provide a parallel group of connections to be connected to a ground or other source potential on a printed circuit board, and provide a low resistance path for carrying current from the power FET. The downset rail 121 and the leads 111 connected to it are also mechanically contacting and electrically coupled to the heat slug 105, which provides a low resistance conductor carrying the potential. Leads 124 are additional overhanging leads arranged to be connected to signals for coupling to the second semiconductor device 117, leads 124 are positioned overhanging and spaced from the heat slug 105 and electrically isolated from it.

To connect the package substrate 109 to the heat slug 105, several alternative approaches can be used. The posts 127 can be formed into mechanical rivets. In this approach, posts 127 of the heat slug 105 extend through openings in the lead frame of package substrate 109 and the posts can be mechanically pressed to hold the lead frame to the heat slug 105. FIG. 1E illustrates in a cross section an alternative for making mechanical connections for areas 129, where the package substrate 109 includes, at the locations of posts 127, a spring contact. By thinning a portion of the package substrate 109 on the side to be mounted to the heat slug 105, a spring contact 131 is formed. Forcing the spring contact 131 towards the heat slug 105 (as shown by the force arrows in FIG. 1E) will put mechanical force on the package substrate 109, forcing the heat slug side of the package substrate 109 into mechanical contact with the heat slug 105.

FIG. 1F illustrates, in a plan view, an alternative approach. In FIG. 1F, a board side plan view of the package substrate 109 is shown with heat slug 105, looking towards the board side surface of the heat slug 105. Die mount area 123 has a first semiconductor device, a power FET 115, and a second semiconductor device, 117 shown. Ultrasonic weld points 108 are shown in several locations, these ultrasonic welds mechanically attach the package substrate 109 to the heat slug 105. Welds 108 are made in along downset rail 121, and in areas 129, these downset portions of the package substrate 109 are in electrical and mechanical contact with the heat slug 105. Overhanging leads 110, and 124, are shown as in FIG. 1D, along with downset leads 111 that are coupled to the downset rail 121. Also shown in FIG. 1F are bond pads 125 on both the power FET semiconductor device 115 and the gate driver device 117. The bond pads face away from the heat slug and are arranged to provide electrical connections to the source, gate, drain terminals and power connections for the power FET, and to provide electrical connections to signals and ground and power connections for the second semiconductor device 117, the gate driver device in the arrangements.

FIG. 1G is a plan view of the package substrate 109 and the heat slug 105 viewed from the board side of heat slug 105, with die mount area 123, and illustrating the electrical connections between the first semiconductor device 115, the second semiconductor device 117, and the leads 101 of the package substrate 109, in this example wire bonds are used for the electrical connections. Note that in FIG. 1G the leads 101 are only shown in part, with the portions outside of the package body omitted for simplicity of illustration.

In FIG. 1G, the overhanging leads include leads 110 arranged for drain connections to the power FETs in the first semiconductor device 115, and overhanging leads 124 which are arranged for signal connections to the second semiconductor device 117, which in this example is a gate driver for the power FET in the first semiconductor device 115. The leads 111 are downset and connected to the downset rail 121, the downset leads 111 and downset rail 121 contacting the heat slug 105. Mounting areas 129 include posts 127 which can be mechanical rivets, or spring contacts as shown in FIG. 1E. Alternatively, ultrasonic welds can be used as shown in FIG. 1F.

In the arrangements, advantages are obtained by use of the downset rail 121. The downset rail 121 of the package substrate 109 is used in the arrangements to provide reduced inductance on certain connections. The second semiconductor device 117 has an input connection AGND. AGND is an analog ground signal that should be low impedance and should be isolated from switching noise to ensure proper performance of the devices. In gate driver and power FET combinations of the arrangements, the signal AGND is coupled to a common source of the power FETs within the first semiconductor device 115, which are also arranged to be connected to a voltage potential together, for example a ground connection. As shown in FIG. 1G for example, ground bond wires 114 connecting the AGND bond pads on semiconductor device 117 to the downset rail 121 provide a short connection path to the downset rail 121, which is further to be connected to the common source terminals of the power FETs within the first semiconductor deice 115 by additional parallel source bond wires 116. The leads 111 that are connected to the downset rail 121 provide the source terminals for the packaged semiconductor device, in an example application these leads are to be connected to a ground trace on a printed circuit board and are at the same potential as the AGND input to the second semiconductor device 117.

In contrast to the arrangements, in a conventional package without these features, the connection between the ground input AGND to the second semiconductor device and the common source connections to the first semiconductor device would be made on a trace formed on a circuit board placed outside of the semiconductor device package. In that case, the signals traverse bond wires twice, the lead frame leads twice, and the circuit board trace to make the ground connections between the semiconductor devices, a substantially higher inductance path when compared to the connections made using the downset rail internal to the package that is formed using the arrangements.

The use of the arrangements including bond wires coupled to the internal downset rail to form connections between the semiconductor devices within the package substantially increases performance over similar packages formed without the arrangements. In an example, using an integrated GaN FET and gate driver device, the inductance measured on an AGND signal was reduced from 2.3 nanohenrys to 0.43 nH. The inductance of the common source connections to the power FET was reduced from 0.5 nanohenrys to 0.12 nH. The overall package resistance was reduced from 2.98 mΩ to 1.99 mΩ. These reductions were achieved with only about a 2.5% cost increase for the completed packaged semiconductor device.

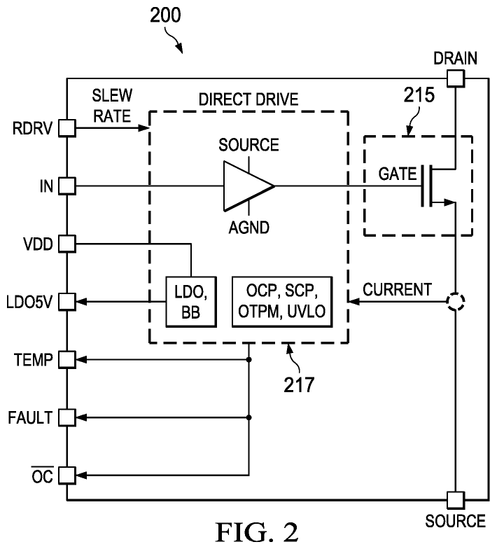

FIG. 2 illustrates in a circuit block diagram 200 a power FET and gate driver in an example arrangement. A power FET 215, in this example a GaN FET, has a drain terminal, a source terminal and a gate terminal labeled GATE. A gate driver device 217 has an output coupled to the GATE terminal. The gate driver device controls the gate potential of the GaN FET, and provides various status signals. The gate driver device 217 has a input terminal IN configured for a gate input signal from a system controller, and a slew rate control input RDRV. The gate driver device 217 has status output signals including a low drop out signal LDO5V, an over temperature signal TEMP, an overcurrent signal OC_, and a fault signal FAULT_. The gate driver device 217 has sensors including an overcurrent protect circuit OCP, a short circuit protect circuit SCP, an over temperature protect circuit OTP, and an under voltage lock out circuit UVLO, these circuits can sense conditions that could damage the GaN FET 215, and in some arrangements the gate driver circuit 217 can shut down current flow through the GaN FET 215 to protect the device from being damaged in the event of a short circuit or overcurrent condition at a load, or in the case of an over temperature condition or an under voltage condition. The ground signal AGND to the gate driver circuit will be connected to a ground trace where the common source signal SOURCE is also connected.

The circuit 200 corresponds to the function provided by the packaged semiconductor device package 100 of FIG. 1A, an integrated combined power FET and gate driver device. In example applications these devices can be used as high side and low side devices in a variety of switching circuits to implement various power circuits.

In the arrangements, the inductance of a gate loop formed by the ground signal AGND to the gate driver 217 to and the common source connection SOURCE to the GaN FET power FET 215, is reduced. When the inductance of this gate loop is high, and the gate driver 217 tries to shut off the GaN FET 215 after a switching operation, oscillations or ringing occur. These oscillations are of sufficient voltage that the gate voltage is sometimes greater than the threshold Vgs for the GaN FET so that it takes time for the GaN FET to completely turn off. In an example package formed without the arrangements, a GaN FET device may remain active longer for several nanoseconds before turning off, after a gate voltage transition so that the device turn off time is increased by these oscillations. When the arrangements for the semiconductor device package with the downset rail are used, and the ground connections to the source and the AGND connections are made to the downset rail within the package, the inductance on the source and ground connections are reduced, the oscillations in the gate loop circuit are reduced or eliminated, and the turn off time for the GaN FET is shortened. The arrangements improve performance of the power FET devices by providing a low inductance package and by including the integral heat slug, with the semiconductor devices mounted directly on the heat slug, which has exposed surfaces for dissipating heat, further improving performance in carrying currents at high voltages of several hundred volts.

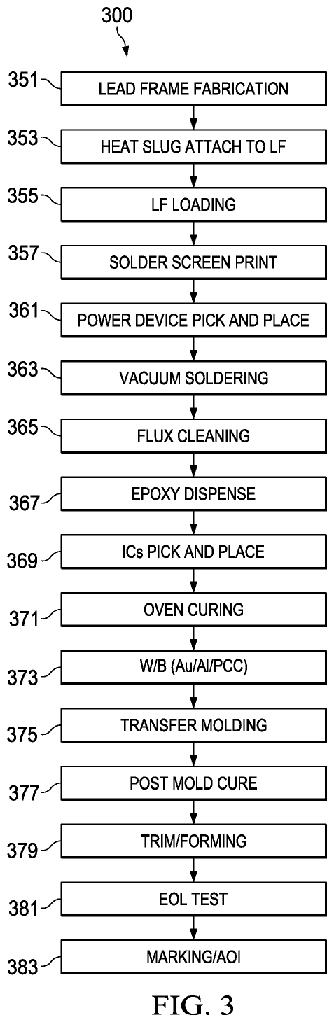

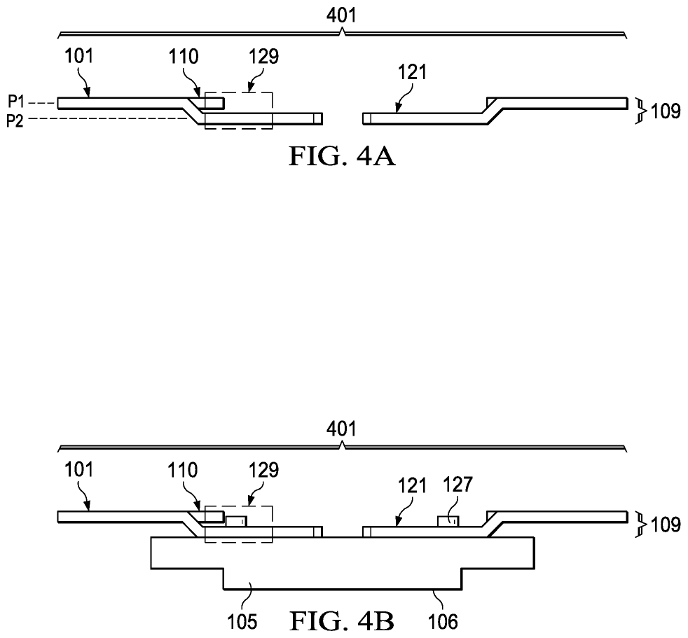

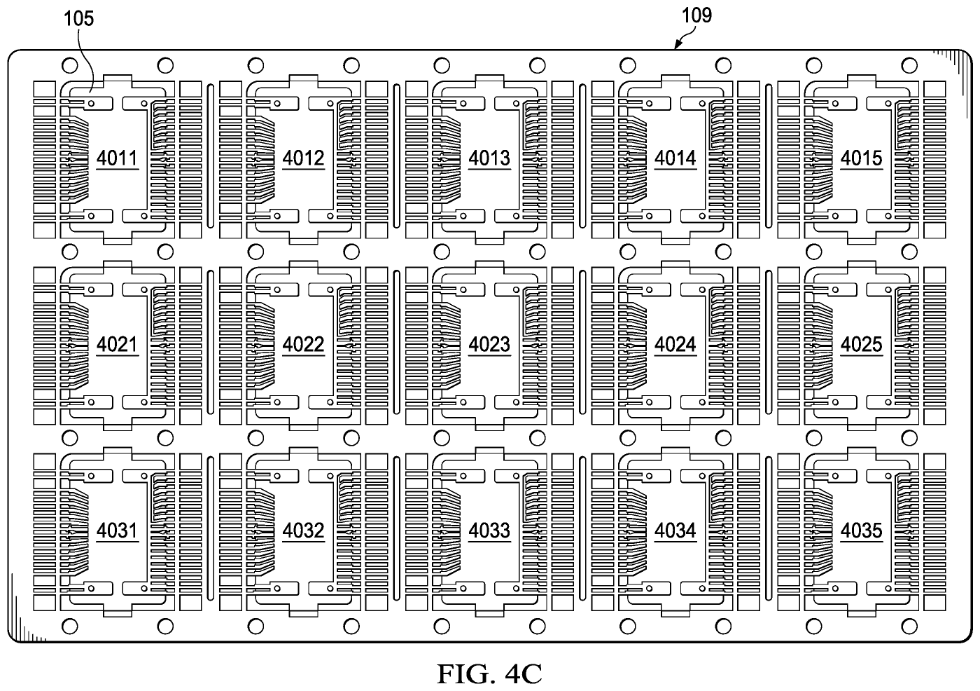

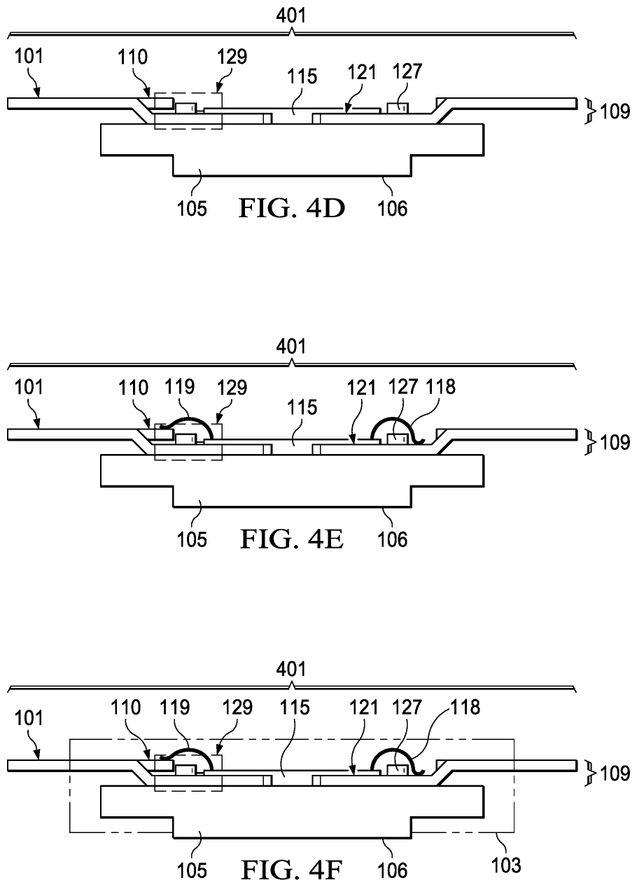

FIG. 3 illustrates, in a flow diagram, selected steps for a method of forming an arrangement. FIGS. 4A-4F illustrate, in a series of views, the results of selected steps of FIG. 3. FIG. 1C is an end view of a completed semiconductor device package that can be formed using the methods.

In FIG. 3, lead frames are first formed at step 351. The lead frames can be formed by stamping or etching a metal sheet material, such as a copper or aluminum sheet material, and plating can be performed to improve bonding and reduce tarnish and corrosion. In one example a preplated lead frame is used. The lead frames can be shaped to add the downset portions, so that the lead frame has the overhanging leads in a first plane, and the downset portions in a second plane. The downset portions will be mounted to the heat slugs as described above.

In forming package substrate 109, in an example process a flat sheet of conductor material is first patterned to form an array of unit lead frames with leads having tie bars and dam bar portions temporarily connecting the leads to provide mechanical support during processing. The tie bars and dam bars will be removed or trimmed away from the finished packaged devices after molding and sawing. In an example a copper sheet material is used. The flat sheet of conductor material can be stamped, punched, or etched to form the patterns. Half etched lead frames can be formed by etching the sheet material separately from both sides of the flat material using different patterns. The flat sheet of conductor material is then shaped in metal shaping tools to form the downset portions, by pushing on portions of the flat sheet and forming angular supports that extend downward to the downset portions.

FIG. 4A illustrates a unit leadframe 401 after the leadframe formation. In a process the unit leadframe 401 is one of an array or strip of identical leadframes in package substrate 109. In an example, package substrate 109 is copper lead frame material. Leads 101 are formed in a first plane P1, with the downset portions formed in a second parallel plane P2. The downset rail 121, and mounting areas 129, are downset from the leads 101. The overhanging leads, such as 110, are formed in the plane P1 and are not downset, remaining in plane P1. The planes P1 and P2 are parallel to one another.

Returning to FIG. 3, the method continues at step 353, where the heat slugs and the lead frames are attached to one another. The attachments can be by forming mechanical rivets, the spring contacts, or ultrasonic welds, as is described above. FIG. 4B illustrates, in an end view, the lead frame and heat slug for one unit device 401 after step 353. Package substrate 109 includes leads 101, including overhanging leads 110, a downset rail 121, and in mounting areas 129, a post 127 which can be used to form the mechanical connections between the heat slug 105 and the package substrate 109.

FIG. 4C illustrates the package substrate 109 in a plan view, showing an array of the unit lead frames, with heat slugs 105 attached, ready for further processing. In FIG. 4C, the package substrate includes three rows and five columns of unit lead frames, so that the unit lead frames 4011, 4012, 4013, 4014 and 4015 are in the top row, and unit lead frames 4021, 4022, 4023, 4024 and 4025 are in the middle row, with unit lead frames 4031, 4032, 4033, 4034 and 4035 in the bottom row. More rows or columns can be used, depending on the package substrate material used. The unit lead frames will be processed simultaneously to form packaged semiconductor devices, and will be separated from one another by sawing at the end of the molding process steps to form individual semiconductor device packages.

At step 355 in FIG. 3, the lead frame and heat slug assemblies are loaded into an assembly tool (not shown) for mounting the semiconductor devices, for example a pick and place tool. As shown in FIG. 4C, the lead frames are provided in an array or matrix of unit devices in rows and columns, so that multiple assemblies will be packaged in parallel to improve throughput and lower costs. The lead frames and heat slugs can be assembled and provided in arrays or strips to a semiconductor manufacturer or to a semiconductor packaging house, for example. The lead frames and heat slugs can be manufactured and assembled independently and in advance of the remainder of the method to form the arrangements.

At step 357 in FIG. 3, the assembly and packaging operations continue by performing a solder screen print on the heat slugs. Solder is printed where the power FET devices will be mounted in die mount areas on the heat slugs.

At step 361, a first pick and place operation is performed to place the power FET devices 115 onto the heat slug 105. At step 363, a vacuum soldering process melts and forms a solder joint between the power FET semiconductor devices and the heat slugs. At step 365, a post solder flux cleaning step is performed to complete the die mount process for the power FET devices. FIG. 4D illustrates in another end view the results of these steps, with power FET 115 shown mounted to the heat slug 105, and the leads such as 110 arranged around the power FET semiconductor device.

At step 367, the die attach epoxy is dispensed for the second semiconductor devices 117, the gate driver semiconductor integrated circuits (ICs). At step 369, a second pick and place operation picks up the second semiconductor devices, the gate driver ICs, and mounts them onto the heat slugs in the die mount area. A die attach epoxy cure is performed at step 371, for example an oven is used to thermally cure the die attach epoxy.

At step 373, wire bonding is performed. In wire bonding, a wire bonding tool includes a capillary with a bond wire running through it. In useful examples, the bond wire can be copper, palladium coated copper (PCC), gold, silver or aluminum. To begin forming a wire bond, a “free air” ball is formed on the end of the bond wire as it extends from the capillary by a flame or other heating device directed to the end of the wire. The ball is placed on a conductive bond pad of a semiconductor die and the ball is bonded to the bond pad. Heat, mechanical pressure, and/or sonic energy can be applied to bond the ball to the bond pad. As the capillary moves away from the ball bond on the bond pad, the bond wire is allowed to extend from the capillary in an arc or curved shape. The capillary moves the wire over a conductive portion of the package substrate, for example a spot on a lead of a lead frame. The capillary in the wire bonder is used to bond the bond wire to the conductive lead, for example a stitch bond can be formed. After the stitch bond is formed to the conductive lead, the wire extending from the stitch bond is cut or broken at the capillary end, and the process starts again by forming another ball on the end of the bond wire. Automated wire bonders can repeat this process very rapidly, many times per second, to form bond wires. This process is referred to as “ball and stitch” bonding. In an alternative, a ball is first bonded to a lead or other surface. A second ball is formed and bonded to a bond pad on the semiconductor die, and the bond wire is extended to the first ball, and bonded to the ball with a stitch on the ball, this is sometimes referred to as “ball stitch on ball” or “BSOB” bonding. In some example processes, the ball bonds are more reliable than stitch bonds, and the extra ball bonds increase the bond reliability.

The bond wires in the example arrangements electrically couple the drain bond pads on the power FET, the first semiconductor device, to overhanging leads, and the gate connections are made between bond pads on the second semiconductor device, the gate driver, and corresponding bond pads on the first semiconductor device, the power FET. In the example arrangements, the source connections and the ground connections (SOURCE and AGND in FIG. 2) are made to the downset rail of the lead frames, as described above. The bond wires can be any used in semiconductor packaging, including gold (Au), aluminum (Al), copper and in a particular example palladium coated copper (PCC), and additional platings such as gold can be used over the bond wires. In an alternative, ribbon bonding can be used. In a further alternative, clip connections can be used for the source and drain common connections to the power FET devices, where conductive metal clips connect the leads of the lead frame to the bond pads.

FIG. 4E is an end view illustrating the unit device 401 after the wire bonding in step 373. A bond wire 118 connects a bond pad on the power FET 115 to the downset rail 121, for example this can be a common source connection. A bond wire 119 connects another bond pad on the power FET 115 to an overhanging lead, such as a drain connection. Additional electrical connections are made as shown in the plan view in FIG. 1G.

Method 300 then continues by performing transfer molding at step 375. A mold compound is provided, for example a thermoset epoxy resin mold compound, an epoxy, a resin or a plastic is used. In an example process, a solid pellet or powdered mold compound is heated in a mold to a liquid state, and then forced under pressure through channels in the mold to surround the unit lead frames including the semiconductor devices to form a package body. At step 377 the mold compound is cured by cooling or by another cure method depending on the mold compound used. As the mold compound cools it cures into a solid package body for each semiconductor device package for the semiconductor devices.

FIG. 4F illustrates in a further end view a unit device 401 after the mold compound 103 is formed in steps 375 and 377 in FIG. 3. The package substrate 109 is shown with mold compound 103 covering semiconductor device 115, the bond wires 119, 118, the overhanging leads 110 and the downset rail 121, and portions of the heat slug 105 and the leads 101, the leads 101 extending from the mold compound 103, and an exposed surface 106 of the heat slug 105 that is not covered by the mold compound 103 for thermal dissipation.

Returning to FIG. 3, at step 379 the leads are trimmed and formed. A cutting process singulates the molded packaged devices one from another by first cutting through the package substrate in saw streets defined between devices, and then trimming and forming the leads to complete the packaged semiconductor devices. The exposed portions of the leads 101 that extend from the mold compound of the packaged semiconductor devices are shaped to form the foot portions 104 (see FIG. 1C) of the leads for surface mounting to a board. At step 381, testing such as end of line (EOL) testing and functional testing is performed on the semiconductor device packages to ensure reliability in the field. Finally, at step 383, automated optical or visual inspections (AOI) can be performed to ensure the devices are correctly molded and that the leads are correctly formed, and marking of the device and lot information is performed on the packaged devices that passed the tests and inspections. The completed packaged semiconductor device is shown in FIG. 1C in an end view, and FIGS. 1A and 1B shown the completed semiconductor device package in projection views.

Use of the arrangements provides a packaged semiconductor device including a power FET semiconductor device with reduced inductance and enhanced thermal dissipation, without changes to the design of the semiconductor dies, while using existing lead patterns and package body sizes. An integrated gate driver device can also be mounted in the packages using the arrangements. Use of the arrangements does not require changes to printed circuit board layouts used to mount the devices. The arrangements are formed using existing methods, materials and tooling for making the devices and are cost effective. By providing a downset rail coupled to the heat slug that is compatible with existing packages, the thermal performance of SOP packages and semiconductor device packages can be enhanced with use of the arrangements while also reducing inductance. Although SOP packages are the examples shown in the illustrations, other package types can be used with the arrangements.

Modifications are possible in the described arrangements, and other alternative arrangements are possible within the scope of the claims.

What is claimed is:

1. An apparatus, comprising:
a heat slug having a board side surface and an opposite top side surface;
a package substrate mounted to the heat slug, the package substrate comprising leads including overhanging leads extending over the board side surface of the heat slug, the package substrate having downset portions including a downset rail that runs along one side of a die mount area on the board side surface of the heat slug, the downset portions of the package substrate lying in a first horizontal plane and the overhanging leads lying in a second horizontal plane parallel to and spaced from the first horizontal plane, the downset portions of the package substrate mechanically attached to and electrically coupled to the board side surface of the heat slug, and the overhanging leads spaced from and electrically isolated from the heat slug;
at least one semiconductor device having a backside surface mounted to the board side surface of the heat slug, the at least one semiconductor device having bond pads on a device side surface facing away from the board side surface of the heat slug;
electrical connections coupling bond pads of the at least one semiconductor device to the overhanging leads of the package substrate and to the downset rail; and
mold compound covering the at least one semiconductor device, the electrical connections, a portion of the leads of the package substrate, and the board side surface of the heat slug, the top side surface of the heat slug at least partially exposed from the mold compound.

2. The apparatus of claim 1, the leads having portions extending from the mold compound to form terminals.

3. The apparatus of claim 2, wherein the portions of the leads extending from the mold compound are shaped to extend alongside a package body formed by the mold compound, the terminals formed by the leads having foot portions configured for surface mounting to a circuit board.

4. The apparatus of claim 1, wherein the top side surface of the heat slug is configured for mounting a heat sink.

5. The apparatus of claim 1, wherein the electrical connections comprise wire bonds, ribbon bonds or conductive clips.

6. The apparatus of claim 1, wherein the package substrate comprises a metal lead frame.

7. The apparatus of claim 6, wherein the metal lead frame further comprises copper, stainless steel, steel, alloy 42, or alloys thereof.

8. The apparatus of claim 1, wherein the heat slug comprises copper, gold or aluminum.

9. The apparatus of claim 1, wherein the mold compound forms a package body that, with the leads, forms a small outline package (SOP).

10. The apparatus of claim 1, wherein the at least one semiconductor device comprises a power FET semiconductor device.

11. The apparatus of claim 10, wherein the power FET semiconductor device comprises a silicon carbide (SiC) FET device or a gallium nitride (GaN) FET device.

12. The apparatus of claim 10, wherein the power FET semiconductor device has drain terminals coupled to the overhanging leads of the package substrate by the electrical connections which are wire bonds, and has source terminals coupled to the downset rail of the package substrate by wire bonds.

13. The apparatus of claim 1, and further comprising:
a second semiconductor device mounted to the heat slug in the die mount area on the board side surface of the heat slug and having a bond pad for a ground connection electrically connected to the downset rail of the package substrate.

14. The apparatus of claim 13, wherein the second semiconductor device further comprises a gate driver device having bond pads electrically coupled to gate input bond pads on the power FET semiconductor device.

15. A power FET packaged semiconductor device, comprising:
a package substrate mounted to a board side surface of a heat slug, the package substrate comprising leads including overhanging leads that extend over and are spaced from the board side surface of the heat slug, and a downset rail attached to the board side surface of the heat slug, the downset rail extending along one side of a die mount area on the board side surface of the heat slug;
a power FET semiconductor device having a backside surface mounted to the board side surface of the heat slug in the die mount area and having bond pads coupled to FET devices formed on a device side surface facing away from the board side surface of the heat slug, and a gate driver semiconductor device having a backside surface mounted to the board side surface of the heat slug in the die mount area, and having bond pads on a device side surface facing away from the board side surface of the heat slug;
electrical connections coupling bond pads of the power FET semiconductor device corresponding to drain terminals of the FET devices to the overhanging leads of the package substrate and coupling bond pads of the semiconductor die corresponding to source terminals of the FET devices to the downset rail;
additional electrical connections coupling bond pads of the power FET semiconductor device corresponding to gate terminals of the FET devices to bond pads of the gate driver semiconductor device and coupling a bond pad for a ground connection of the gate driver semiconductor device to the downset rail; and
mold compound covering the power FET semiconductor device, the gate driver semiconductor device, the electrical connections, the additional electrical connections, a portion of the leads, and a portion of the heat slug, the heat slug having a top side surface opposite the board side surface that is exposed from the mold compound.

16. The power FET packaged semiconductor device of claim 15, wherein the top side surface of the heat slug is configured for mounting a heat sink.

17. The power FET packaged semiconductor device of claim 15, and the package substrate further comprising downset leads that extend to the downset rail and form source terminals.

18. The power FET packaged semiconductor device of claim 15, wherein the electrical connections and additional electrical connections are bond wires, ribbon bonds, or conductive clips.

19. The power FET packaged semiconductor device of claim 15, wherein the power field effect transistor (FET) semiconductor device is a silicon carbide (SiC) FET device or a gallium nitride (GaN) FET device.

20. The apparatus of claim 15, wherein the power FET semiconductor device package is a small outline package (SOP).

21. A method, comprising:
mounting a package substrate to a board side surface of a heat slug, the package substrate comprising overhanging leads extending over the board side surface of the heat slug and comprising a downset rail mounted to the board side surface of the heat slug, the downset rail extending along one side of a die mount area on the board side surface of the heat slug;
mounting a power FET semiconductor device to the board side surface of the heat slug, the power FET semiconductor device having a backside surface mounted to the board side surface of the heat slug and having a device side surface with bond pads coupled to FET devices on the device side surface;
mounting a gate driver semiconductor device to the board side surface of the heat slug, the gate driver semiconductor device having a backside surface mounted to the board side surface of the heat slug in the die mounting area, and having bond pads on a device side surface facing away from the board side surface of the heat slug;
forming electrical connections coupling bond pads corresponding to drain terminals for FET devices on the power FET semiconductor device to the overhanging leads and coupling bond pads corresponding to source terminals on the power FET device to the downset rail;
forming additional electrical connections coupling a bond pad corresponding to a ground signal on the gate driver semiconductor device to the downset rail; and
covering the power FET semiconductor device, the gate driver semiconductor device, the electrical connections and the additional electrical connections with mold compound to form a packaged semiconductor device, the package substrate leads having portions extending from the mold compound to form terminals, the heat slug having a top side surface opposite the board side surface that is exposed from the mold compound.
